(19) United States
(12) Patent Application Publication
(10) Pub. No.: US 2005/0257745 A1
(43) Pub. Date: Nov. 24, 2005

(54) Film formation source, vacuum film formation apparatus, method of manufacturing organic EL device, and organic EL device

(75) Inventors: Hirosi Abiko, Yamagata-ken (JP); Daisuke Masuda, Yamagata-ken (JP); Shigehiro Umetsu, Yamagata-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Tohoku Pioneer Corporation, Tendo-shi (JP)

(21) Appl. No.: 11/123,180

(22) Filed: May 6, 2005

(30) Foreign Application Priority Data
May 20, 2004 (JP) 2004-150954

(51) Int. Cl. C23C 16/00

(52) U.S. Cl. 118/726

(57) ABSTRACT

Film formation is conducted with a high level of directivity. A film formation source of a vacuum film formation apparatus, comprises a material container for housing a film forming material, heating means for heating the film forming material inside the material container, and a rectifier provided at an ejection port of the material container. In this source, the rectifier comprises a passage partitioned into fine openings, and a set directivity is obtained on the basis of the cross-sectional area Sa of each opening within the rectifier, the distance L from the ejection tip of the rectifier to the film formation target surface, and the film formation rate R for the film forming material at a point on the film formation target surface directly above the center of the rectifier.

### BACKGROUND OF THE INVENTION

The present invention relates to a film formation source, a vacuum film formation apparatus, a method of manufacturing an organic EL device, and an organic EL device.

The present application claims priority from Japanese Patent Application No. 2004-150954, the disclosure of which is incorporated herein by reference.

Vacuum film formation methods (including vacuum deposition and molecular beam epitaxy methods) are known as favorable techniques for forming thin films on substrates. In a vacuum film formation method, an atomic flow or molecular flow of a film forming material, generated by subliming or vaporizing the film forming material through heating, is irradiated onto the film formation surface of a substrate positioned inside a vacuum film formation chamber, thereby bonding the film forming material to this film formation surface, and forming a thin film. A vacuum film formation apparatus for conducting this type of vacuum film formation typically has a basic construction comprising a film formation source, equipped with at least a container, known as a crucible or a cell, for holding the film forming material, and heating means for heating the film forming material, as well as the vacuum film formation chamber described above.

This type of vacuum film formation is employed for forming thin films in all manner of electronic equipment. In particular, it is used during the manufacture of organic EL devices, which have recently been attracting considerable attention as display elements for self-emitting flat panel displays, for forming electrodes or organic material layers including luminescent layers on a substrate.

One property required of the film formation source during vacuum film formation, is a high level of directivity. In this description, a high level of directivity refers to the ability to emit the atomic or molecular flow, generated by subliming or vaporizing the film forming material through heating, in a desired direction, with no outward dispersion of the flow. In quantitative terms, this property refers to the ability to reduce the half width of the distribution of the film thickness of the generated thin film.

By using a film formation source with a high level of directivity, the film forming material is not scattered wastefully, meaning the usage efficiency of the material can be maximized. Furthermore, concentrated film formation can be conducted at the desired locations, meaning provided the film formation is conducted at a reasonable rate, the operational efficiency of the film formation process can also be improved.

In a method of manufacturing an organic EL device, a high level of directivity enables the productivity to be improved, by maximizing the usage efficiency of the valuable organic material, and improving the operational efficiency of the film formation process. This enables a reduction in the cost of the product, as well as an improvement in the product quality, as a result of improved film formation precision.

A variety of different film formation sources for producing high levels of directivity have been proposed. For example, Japanese Patent Application Laid-Open No. Hei 6-228740 discloses a structure in which a nozzle for ejecting a vaporized flow is provided above the vapor deposition source of the vacuum deposition apparatus, and the shape of the nozzle ejection port is modified in accordance with the deposition region of the deposition target. Furthermore, Japanese Patent Application Laid-Open No. 2003-293120 discloses a structure in which a long container that houses a vaporization material is provided as the vapor deposition source of the vacuum deposition apparatus. Hole-shaped vaporization apertures are provided along the lengthwise direction of this long container, and the aspect ratio (the aperture depth L/the aperture diameter D) for each of these vaporization apertures is set to a value of at least 1.

However, in an actual vacuum film formation process, effectively improving the directivity simply by setting either the shape of the nozzle ejection port of the film formation source, or the aspect ratio of the vaporization apertures, is impossible. FIG. 1 is a graph showing the relationship between the nozzle aspect ratio (the nozzle length L/the nozzle internal diameter D) and the half width ha, under conditions including the provision of a circular cylindrical nozzle at the ejection port of the film formation source, and a uniform film formation rate. FIGS. 2A and 2B are diagrams explaining the definition of the half width ha. As shown in FIG. 2A, the ejection port of the film formation source S is directed towards a substrate M for film formation. If the distribution of the resulting film thickness is as shown in FIG. 2B, then the half width ha is equal to double the distance from a point 0 on the substrate M directly above the ejection port, to the point where the film thickness falls to half the value (t₀/2) of the maximum film thickness to within the film thickness distribution on the substrate surface.

From the graph of FIG. 1 it is clear that even if the nozzle aspect ratio is set to a value of 1 or greater, once a certain value is reached, no further improvement in the directivity (that is, no further narrowing of the half width ha) can be achieved. If the aspect ratio is set to a high value, then the directivity can be increased by lowering the film formation rate, but lowering the film formation rate increases the time required for the film formation, causing an impractical deterioration in the operational efficiency of the film formation process.

### SUMMARY OF THE INVENTION

The present invention aims to solve the problems described above. In other words, an object of the present invention is to ascertain the essential factors that control the directivity of the film formation source, thereby enabling the presentation of design indicators for the film formation source that enable higher levels of directivity to be achieved without lowering the film formation rate. Other objects of the present invention are to provide a vacuum film formation apparatus capable of high directivity film formation at a reasonable rate, and to reduce the manufacturing costs of organic EL devices and improve the associated product quality by conducting film formation with a high level of directivity and a high degree of operational efficiency.

In order to achieve these objects, the present invention comprises at least the structures according to the following independent aspects.

According to a first aspect of the present invention as set forth in claim 1, there is provided a film formation source of a vacuum film formation apparatus, for forming a thin film on a film formation target surface by irradiating an atomic flow or molecular flow, generated by heating, and either subliming or vaporizing, a film forming material, onto the film formation target surface, wherein the film formation source comprises a material container for housing the film forming material, heating means for heating the film forming material inside the material container, and a rectifier provided at an ejection port of the material container, the rectifier comprises a passage partitioned into fine openings, and a set directivity is obtained based on a cross-sectional area Sa of each opening within the rectifier, a distance L from an ejection tip of the rectifier to the film formation target surface, and a film formation rate R for the film forming material at a point on the film formation target surface directly above the center of the rectifier.

### BRIEF DESCRIPTION OF THE DRAWINGS

These and other objects and advantages of the present invention will become clear from the following description with reference to the accompanying drawings, wherein:

FIG. 1 is an explanatory diagram (showing the relationship between the aspect ratio and the half width), used for describing the objects of the present invention;

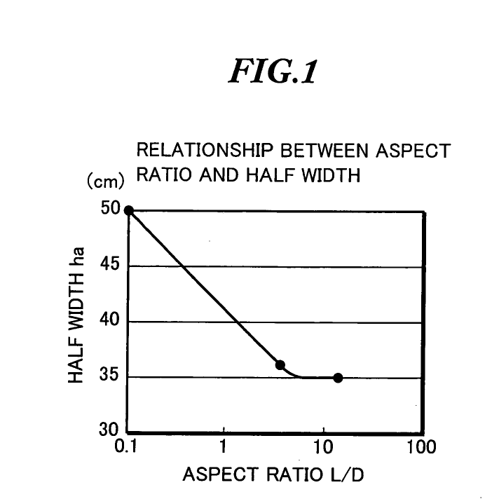

FIGS. 2A and 2B are explanatory diagrams (for defining the half width), used for describing the objects of the present invention;

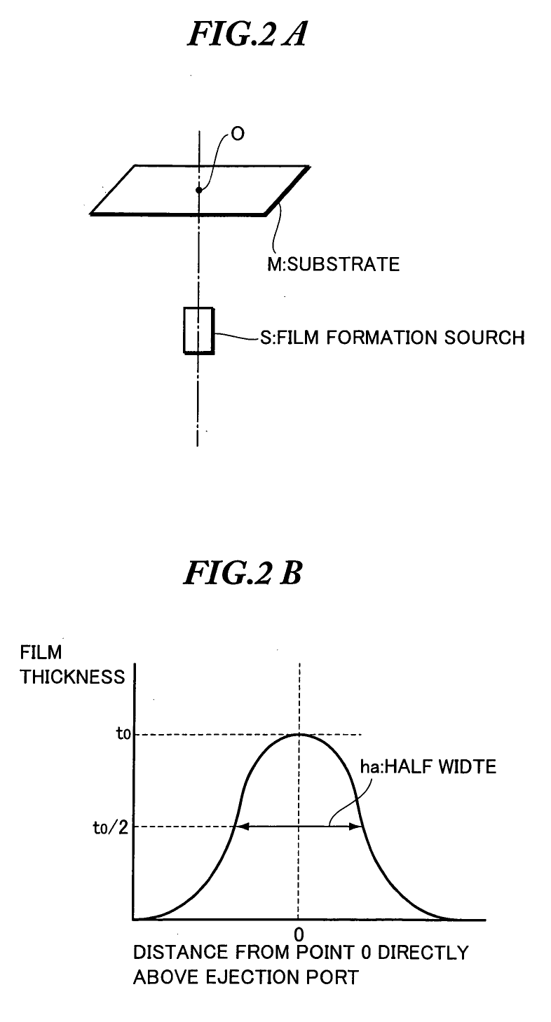

FIG. 3 is an explanatory diagram showing an example of the basic construction of a film formation source according to an embodiment of the present invention;

FIG. 4 is a graph showing the preferred range of settings for a film formation source of the embodiment of the present invention;

FIG. 5 is a graph showing the results for examples and comparative examples of the present invention plotted on the graph of FIG. 4;

FIGS. 6A and 6B are explanatory diagrams showing modified examples of the film formation source of the embodiment of the present invention;

FIGS. 7A through 7D are explanatory diagrams showing sample structures for a vacuum film formation apparatus using a film formation source according to the embodiment of the present invention; and

FIG. 8 is an explanatory diagram showing an example of an organic EL panel manufactured using a vacuum film formation apparatus according to an embodiment of the present invention.

### DETAILED DESCRIPTION OF THE PREFERRED EMBODIMENTS

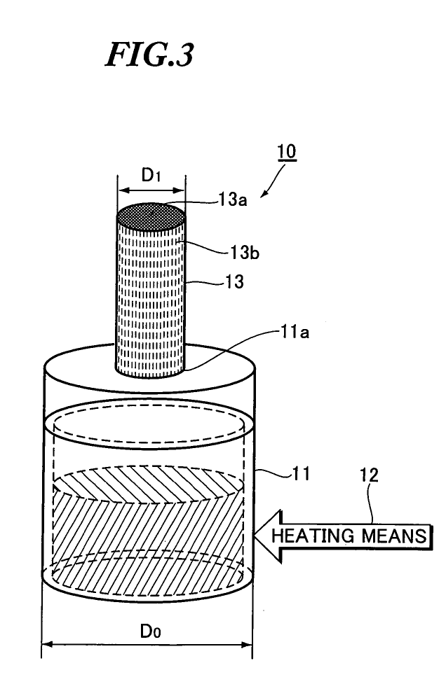

Embodiments of the present invention will be described with reference to the drawings. FIG. 3 is an explanatory diagram showing an example of the basic construction of a film formation source according to an embodiment of the present invention. The film formation source 10 according to this embodiment comprises at least a material container 11 for housing a film forming material, heating means 12 for heating the film forming material housed inside the material container 11, and a rectifier 13 provided at an ejection port 11a of the material container 11. The rectifier 13 contains a passage 13b that has been partitioned into a plurality of fine openings 13a.

The rectifier 13 corresponds with the nozzle used in the conventional art, and has a function of regulating the irradiation direction of the atomic flow or molecular flow of the film forming material generated by heating, and either subliming or vaporizing, the film forming material. The characteristic feature of the present invention is in the introduction, during the design of the rectifier 13, of a specific relationship between the molecular flow density (or the atomic flow density, although hereafter molecular flow density is used as a generic term covering both flow types), and the half width.

In order to improve the directivity of the film formation source 10, it is necessary to establish a state in which intermolecular collisions within the passage 13b of the rectifier 13 are less likely to occur. In other words, it is necessary to establish a state wherein the Knudsen number Ku (=λ/d, wherein λ is the average free path length of a molecules [m], and d is the internal diameter of the passage 13b), which is a dimensionless number used for evaluating the effect of intermolecular collisions during molecular movement, is considerably larger than 1. However, if the film formation rate is lowered to form a state with a high Knudsen number Ku, then as described above, this tends to invite prolongation of the film formation time, making a practical film formation operation impossible.

Accordingly, in this embodiment of the present invention, attention was focused on the molecular flow density within the rectifier 13. In other words, the embodiment was conceived by focusing on the fact that the relationship between the molecular flow density in the rectifier 13 and the half width is a correlation that is dependent on the configuration of the rectifier 13 and the operating state of the film formation source 10. More specifically, it was noticed that the relationship between the common logarithm of the molecular flow density, and the normalized half width was a linear relationship with a positive gradient dependent on the configuration of the rectifier 13 and the operating state of the film formation source 10. Accordingly, this embodiment of the present invention specifies design ranges that provide a configuration for the rectifier 13 and an operating state for the film formation source 10 that are appropriate in terms of maximizing both the directivity and the film formation rate.

Specifically, the molecular flow density X was represented by the formula (a) shown below as a design indicator for the film formation source 10.
X=log(R·L²/Sa)[angstrom/sec] (a)

Sa: the cross-sectional area of each opening 13a within the rectifier 13, L: the distance from the ejection tip of the rectifier 13 to the film formation target surface, and R: the film formation rate for the film forming material at a point on the film formation target surface directly above the center of the rectifier 13.

Furthermore, the normalized half width Y was represented by the formula (b) shown below.
Y=ha/L (b)

ha: the half width during film formation on the film formation target surface, and L: the distance from the ejection tip of the rectifier 13 to the film formation target surface.

The parameters in these formulas (a) and (b) are determined by the operating state of the film formation source 10 and the configuration of the rectifier 13. Accordingly, a desired directivity can be set for the film formation source 10 on the basis of the cross-sectional area Sa of each opening 13a with in the rectifier 13, the distance L from the ejection tip of the rectifier 13 to the film formation target surface, and the film formation rate R for the film forming material at a point on the film formation target surface directly above the center of the rectifier 13.

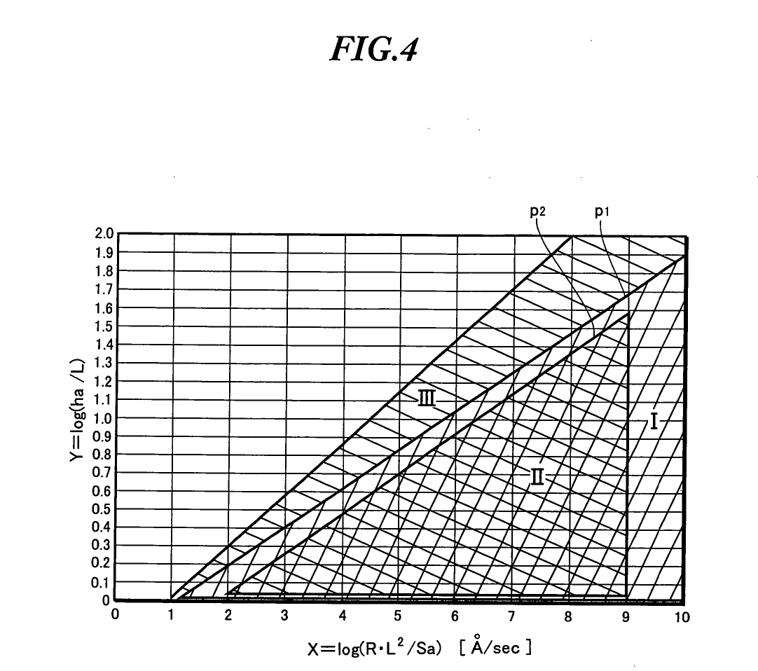

FIG. 4 is a graph showing the preferred range of settings for the film formation source 10 in an embodiment of the present invention. The graph shows the range of settings, with the molecular flow density X, represented by the above formula (a), along the X axis, and the normalized half width Y, represented by the above formula (b), along the Y axis. In the figure, the straight line p1 represents Y=0.21·X−0.2, and the straight line p2 represents Y=0.22·X−0.39. The region III in the figure, which shows Y>0.21·X−0.2, represents the X-Y relationship in those cases where fine openings are not formed within the rectifier 13, as is the case in the conventional art.

The embodiment of the present invention represents a configuration in which for the same molecular flow density X, experimentation has revealed a higher level of directivity (a narrower half width) than that of the region III. The achievable setting range is specified as a region I [1≦X≦10, 0.01≦Y≦0.21·X−0.2], and within this region, particularly preferred settings are specified as a region II [2≦X≦9, 0.05 ≦Y≦0.22·X−0.39]. The establishment of these regions is based on a comparison of the results of measurements conducted for specific examples and comparative examples described below.

The characteristic feature of this embodiment is the use of the formulas X=log(R·L²/Sa) and Y=ha/L as setting parameters. By employing these setting parameters, the directivity of the film formation source 10 can be set on the basis of the molecular flow density, which is the primary factor affecting the directivity. Consequently, in comparison with the conventional art, a higher level of directivity can be achieved while still maintaining a satisfactory film formation rate.

As follows is a description of examples of the present invention. In a film formation source 10 according to an example of the present invention, the diameter D₀ of the material container 11 is larger than the diameter D₁ of the rectifier 13, and a plurality of fine openings 13a are provided inside the rectifier 13, as shown in FIG. 3. The rectifier 13 used either a configuration in which 1600 pipes of internal diameter 0.1 mm and length 20 mm were used to fill the inside of a circular cylindrical body of diameter D₁=8 mm and length 20 mm (example 1), or a configuration in which 220 pipes of internal diameter 0.4 mm and length 20 mm were used to fill the inside of a circular cylindrical body of diameter D₁=8 mm and length 20 mm (example 2).

Furthermore, the comparative examples included a structure in which a nozzle was provided which had an identical outward appearance to the rectifier 13, but contained no fine openings (comparative example 1), and a structure in which the rectifier 13 was removed from the material container 11, and the diameter of the ejection port 11a was reduced to 3.5 mm (comparative example 2).

Using these examples 1 and 2, and comparative examples 1 and 2, the value of L (the distance from the ejection tip of the rectifier 13, or the ejection tip of the nozzle, to the film formation target surface) was set to 300 mm, and film formation was conducted at a variety of different rates, with the half width measured for each rate. The results of the measurements are shown in Table 1.

TABLE 1

| | Ejection | Opening | | | | |
|---|---|---|---|---|---|---|
| | port | cross-sectional | | | | Y (ha/L) |
| | diameter | area Sa | Rate R | X (log) molecular | Half width ha | normalized half |
| | (mm) | (mm²) | (angstrom/sec) | flow density | (mm) | width |
| Example 1 | 8 | 0.00785 | 8.5 | 7.99 | 145 | 0.48 |
| Internal diameter | | | 1.5 | 7.24 | 69 | 0.23 |
| 0.1 mm/1600 pipes | | | 0.33 | 6.58 | 48 | 0.16 |
| Example 2 | 8 | 0.1253 | 24 | 7.24 | 318 | 1.06 |
| Internal diameter | | | 9.1 | 6.81 | 249 | 0.83 |
| 0.4 mm/220 pipes | | | 0.48 | 5.54 | 49 | 0.16 |
| Comparative | 8 | 50.27 | 24 | 4.64 | 320 | 1.07 |
| example 1 | | | 0.22 | 2.60 | 145 | 0.49 |
| No fine openings | | | 10 | 4.27 | 300 | 1 |
| | | | 1.2 | 3.34 | 218 | 0.73 |
| | | | 6.9 | 5.90 | 327 | 1.09 |
| Comparative | 3.5 | 9.621 | 12 | 5.30 | 300 | 1 |
| example 2 | | | 0.24 | 3.36 | 181 | 0.61 |
| No rectifier | | | — | — | — | — |

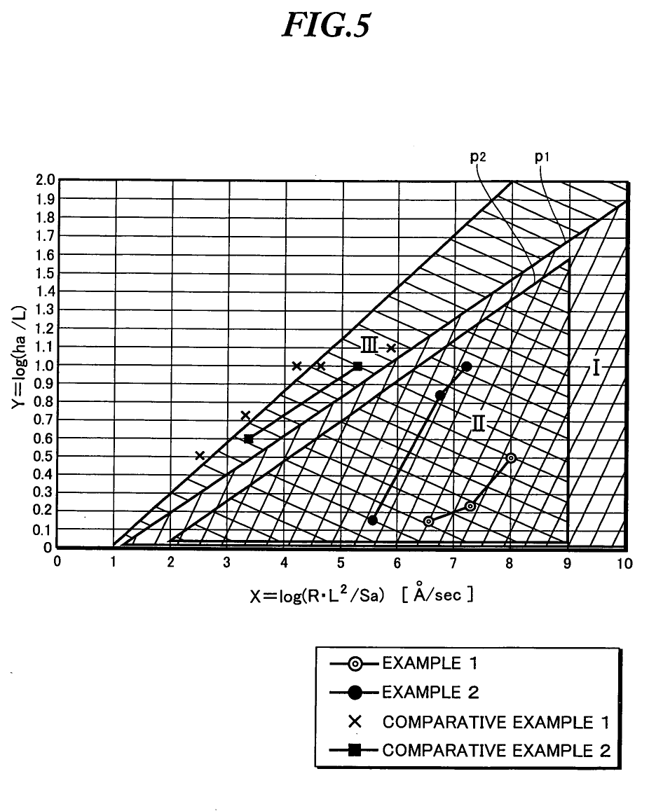

FIG. 5 is a diagram showing the measurement results plotted on the graph of FIG. 4. In FIG. 5, directivity can be considered to increase for smaller values of Y, and the film formation rate can be considered to increase for larger values of X. It is clear that compared with the comparative examples 1 and 2, the examples 1 and 2 enable a higher level of directivity to be achieved at a higher film formation rate.

In the examples of the present invention described above, the rectifier 13 was formed as a circular cylindrical body, and a plurality of pipes were then used to fill this body, thus forming a plurality of fine openings 13 with circular cross sections. However, the present invention is not limited to these structures, and the rectifier 13 may be a polygonal column-shaped body, while the cross-sectional shape of the openings 13a may also be polygons or the like. If the thickness of the partitioning walls of the fine openings is increased, then this can obstruct the passage of vapor through the pipes, leading to problems of material decomposition. Consequently, thinner walls are preferred, provided they are capable of retaining their structural form. Furthermore, the structure of the rectifier 13 may also involve partitioning the ejection port 11a of the material container 11 into a mesh-like pattern, thereby forming fine flow passages. In summary, the embodiment of the present invention does not simply amount to specifying the configuration of the rectifier 13, but rather provides a structure that uses design parameters based on the molecular flow density to improve the directivity of the film formation source 10, even within regions where the directivity cannot be improved by simply increasing the aspect ratio. The structure of the film formation source 10 shown in FIG. 3 represents merely a preferred embodiment for realizing the present invention.

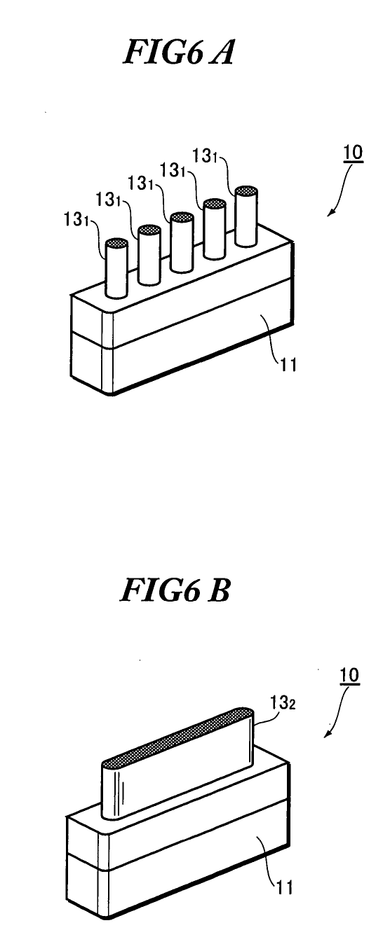

FIGS. 6A and 6B show modified examples of the film formation source 10 shown in FIG. 3. In FIG. 6A, a plurality of the same type of rectifiers 13, used in the embodiment shown in FIG. 3 are arranged in a line above a single material container 11. In FIG. 6B, a rectifier 13₂ with an elongated ejection port, and filled with fine openings, is provided above a single material container 11. These examples represent effective film formation sources for those cases where the film formation requires a high level of directivity in one direction, and a linear broadening of the flow in the orthogonal direction. Furthermore, an integrated structure where the rectifier exists inside the material container is also possible.

There are no particular restrictions on the materials used for forming the material container 11 and the rectifier 13 of an embodiment of the present invention. Suitable materials include nickel, iron, stainless steel, cobalt-nickel alloy, graphite, and magnetic ceramics such as SiC, Al₂O₃, BN, and titanium nitride.

Furthermore, the heating means 12 can also use any of the conventionally known heating means. Examples of suitable heating methods include resistance heating, high frequency heating, laser heating, and electron beam heating. In a preferred embodiment, a resistance heating method is used, and a filament or boat-shaped heating coil, formed from a high melting point metal such as tantalum (Ta), molybdenum (Mo), or tungsten (W), is wound around the periphery of the material container 11, which is formed from a high melting point oxide material such as alumina (Al₂O₃) or berrylia (BeO). Heating is then achieved by passing a current through this heating coil. In an even more desirable embodiment, the rectifier 13 is formed of the same material as the material container 11, and the heating coil is also wound around the periphery rectifier 13. By enabling heating of the rectifier 13 in this manner, adhesion of the film forming material to the rectifier 13 can be prevented, thereby enabling more favorable film formation.

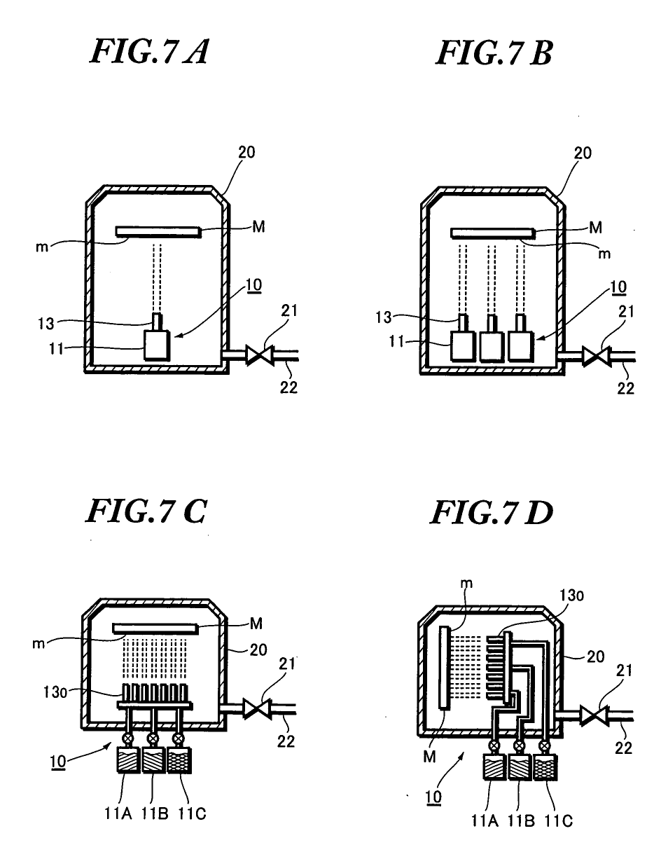

FIGS. 7A through 7D show a series of sample structures for a vacuum film formation apparatus using a film formation source according to the aforementioned embodiment of the present invention. The vacuum film formation apparatuses shown in FIG. 7A through 7D each comprise a film formation source 10 according to the above embodiment of the present invention, and a vacuum film formation chamber 20, in which a substrate M with a film formation target surface m is held using holding means, which are not shown in the figure. In each apparatus, a molecular flow of the film forming material emitted from the film formation source 10 is irradiated onto the substrate M. The vacuum film formation chamber 20 is connected to an evacuation pipe 22 via a valve 21, and the inside of the chamber is able to be evacuated down to a state of high vacuum (no more than 10⁻⁴ Pa). With the chamber held in this state of high vacuum, the film formation source 10 is heated, and a molecular flow of the film forming material is ejected into the chamber, forming a thin film on the substratem. This structure enables the provision of a vacuum film formation apparatus that is capable of high directivity film formation at a reasonable rate.

In the sample structures shown in FIG. 7A and 7B, the film formation source 10 is disposed inside the vacuum film formation chamber 20. Both a structure with a single film formation source 10, such as that shown in FIG. 7A, and a structure with a plurality of film formation sources 10, such as that shown in FIG. 7B, are possible. Furthermore, in the sample structures shown in FIG. 7C and 7D, the rectifiers 13₀ are disposed inside the vacuum film formation chamber 20, while the material containers 11A, 11B, and 11C are disposed outside the vacuum film formation chamber 20. In these examples, a plurality of column-shaped rectifiers 13₀ with ejection ports are aligned along one direction of the substrate, and these are connected to a plurality of material containers 11A, 11B, and 11C. Both a structure in which the molecular flow is ejected in a vertical direction, such as that shown in FIG. 7C, and a structure in which the molecular flow is ejected in a horizontal direction, such as that shown in FIG. 7D, are possible.

A vacuum film formation apparatus using a film formation source 10 described above can be favorably applied to a method of manufacturing an organic EL panel comprising organic EL devices as the display elements. In this type of organic EL panel, an organic material layer containing at least one organic luminescent layer is sandwiched between a first electrode and a second electrode, forming organic EL devices on top of a substrate. The above vacuum film formation apparatus can be used for generating a film of one or more film forming materials on the substrate, during the formation of either the electrodes or the organic material layer.

Because this film formation can be conducted at a favorable rate and with a high level of directivity, wastage of the organic material is limited, and the scale of the operation for recovering unused film forming material can be reduced. As a result, the film formation can be conducted with good operational efficiency, thus enabling a reduction in the production cost of the organic EL devices (and the organic EL panel), as well as an improvement in the product quality. Needless to say, these effects are not limited to organic EL devices, and the same effects could be expected for vacuum thin film formation means such as vacuum deposition incorporating molecular beam epitaxy.

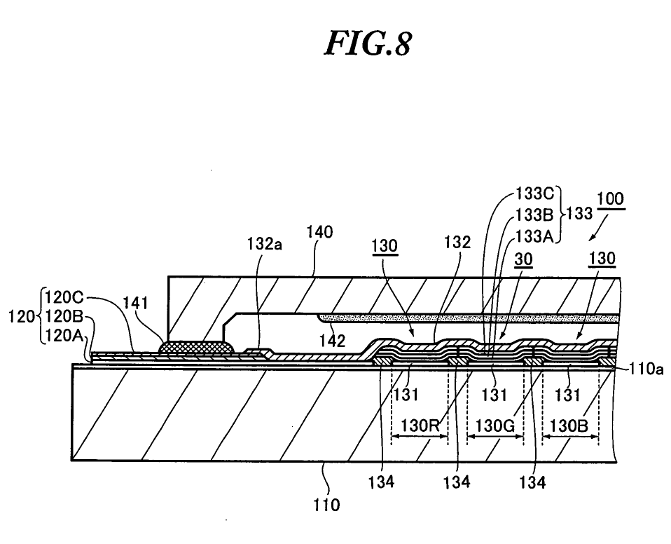

FIG. 8 is an explanatory diagram showing an example of an organic EL panel manufactured using the aforementioned vacuum film formation apparatus.

The basic structure of this organic EL panel 100 comprises an organic material layer 133 containing an organic luminescent layer sandwiched between a first electrode 131 and a second electrode 132, thereby forming a plurality of organic EL devices 130 on top of a substrate 110. In the example shown, a silicon coating layer 110a is formed on top of the substrate 110, and the first electrode 131 formed on top of this coating layer is a transparent electrode such as ITO and functions as the anode, whereas the second electrode 132 is formed from a metal material such as Al and functions as the cathode. This structure is known as a bottom emission system in which light is emitted through the substrate 110 side of the structure. Furthermore, in the example shown, the organic material layer 133 is a three-layered structure comprising a hole transporting layer 133A, a luminescent layer 133B, and an electron transporting layer 133C. A sealed space is formed above the substrate 110 by bonding a sealing member 140 to the substrate 110 via an adhesive layer 141, and the display section comprising the organic EL devices 130 is formed inside this sealed space.

In the display section comprising the organic EL devices 130 shown in the figure, the first electrodes 131 is partitioned by an insulating layer 134, and unit display regions (130R, 130G, 130B) corresponding with each of the organic EL devices 130 are formed beneath the partitioned first electrode 131. Furthermore, drying means 142 are attached to the inside surface of the sealing member 140 that forms the sealed space, thereby preventing deterioration of the organic EL devices 130 caused by humidity.

Furthermore, at least one first electrode layer 120A formed from the same material, and in the same manner as the first electrodes 131 is formed in a pattern at the edge of the substrate 110, and is insulated from the first electrodes 131 by the insulating layers 134. On the protruding portion of this first electrode layer 120A is formed at least one second electrode layer 120B, which generates a low resistance wiring portion comprising a metal such as Ag, Cr, or Al, or an alloy thereof such as a silver-palladium (Ag—Pd) alloy. If necessary, a protective film 120C of IZO or the like may then be formed on top of the second electrode layer 120B, there by completing formation of at least one extraction electrode 120, comprising the first electrode layer 120A, the second electrode layer 120B, and the protective film 120C. The tip of the second electrode 132 is connected to this extraction electrode 120 near the inside edge of the sealed space.

An extraction electrode for the first electrode 131, although not shown in the figure, can be formed by extending the first electrode 131 so that it protrudes beyond the sealed space. An electrode layer that generates a low resistance wiring portion, comprising a metal such as Ag, Cr, or Al, or an alloy thereof, can also be formed on top of this extraction electrode, in a similar manner to that described above for the second electrode 132.

As follows is a more specific description of the organic EL panel 100 according to an embodiment of the present invention, as well as a method of manufacturing such a panel.

a: Electrodes

One of the first and second electrodes 131 and 132 is set as the cathode, while the other is set as the anode. The anode is formed of a material with a higher work function than the cathode, and typically uses a metal film such as chrome (Cr), molybdenum (Mo), nickel (Ni), or platinum (Pt), or alternatively, a transparent conductive film of a metal oxide such as ITO or IZO. In contrast, the cathode is formed of a material with a lower work function than the anode, and typically uses a low work function metal, such as an alkali metal (Li, Na, K, Rb, Cs), an alkaline earth metal (Be, Mg, Ca, Sr, Ba), or a rare earth metal; a compound or an alloy of such a low work function metal; an amorphous semiconductor such as a doped polyaniline or a doped polyphenylenevinylene; or an oxide such as Cr₂O3, NiO, or Mn₂O₅. In those cases where both the first and second electrodes 131 and 132 are formed of transparent materials, a reflective film can be provided on the opposite side of the electrodes to the light emission side.

The extraction electrode 120 is connected to a drive circuit component or a flexible wiring board for driving the organic EL panel 100. The extraction electrode 120 is preferably formed with as low a resistance as possible, and as described above, either a low resistance metal electrode layer is produced by laminating Ag—Pd alloy, or metals such as Ag, Cr, Al, or alloys thereof, or alternatively, a low resistance metal electrode is formed of a single such metal.

b: Organic Material Layer

The organic material layer 133 is formed of an organic compound material layer with either a single layer or multiple layers, and comprises at least a layer with an organic EL function, although the actual configuration of the layers is flexible. As shown in FIG. 8, generally an organic material layer is used that comprises a hole transporting layer 133A, a luminescent layer 133B, and a electron transporting layer 133C, laminated in that order, from the anode side towards the cathode side. However, a plurality of any one of the luminescent layer 133B, the hole transporting layer 133A, and the electron transporting layer 133C may be provided, and either one, or both, of the hole transporting layer 133A and the electron transporting layer 133C may also be omitted. Furthermore, depending on the intended application, other organic material layers such as hole injection layers and electron injection layers can also be inserted within the organic material layer. In the present invention, the hole transporting layer 133A, the luminescent layer 133B, and the electron transporting layer 133C can use any of the conventionally used materials (including both high molecular weight materials and low molecular weight materials) Furthermore, the light emitting material for forming the luminescent layer 133B may employ either light emission generated during the return from an excited singlet state to a ground state (fluorescence), or light emission generated during the return from an excited triplet state to a ground state (phosphorescence).

c: Sealing Member (Sealing Film)

In the organic EL panel 100, the sealing member 140 used for sealing the organic EL devices 130 in an air-tight state can use a sheet-like member or a vessel-shaped member formed from metal, glass, or plastic. A glass member can be formed by press molding, etching or blast treatment of a glass sealing sheet to form a sealing depression (with either single grooves or double grooves). Alternatively, a flat sheet of glass can be used, and glass (or plastic) spacers then used to create the sealed space between the glass sheet and the substrate 110.

Instead of using the sealing member 140, the organic EL devices 130 can also be sealed in an air-tight state by covering the organic EL devices 130 with a sealing film. This sealing film can be formed of either a single film layer, or a plurality of protective films laminated together. The materials used can be either inorganic or organic materials. Examples of suitable inorganic materials include nitrides such as SiN, AlN, and GaN, oxides such as SiO₂, Al₂O₃, Ta₂O₅, ZnO, and GeO, oxynitrides such as SiON, carbonitrides such as SiCN, metal fluorine compounds, and metal films. Examples of suitable organic materials include epoxy resins, acrylic resins, polyparaxylene, fluoropolymers such as perfluoroolefins and perfluoroethers, metal alkoxides such as CH₃OM and C₂H₅OM, polyimide precursors, and perylene-based compounds. The structure of the sealing film and the materials used can be selected during design of the organic EL devices 130.

d: Adhesive

The adhesive for forming the adhesive layer 141 can use a thermosetting adhesive, a chemical curing adhesive (a two-pot adhesive), or a light (ultraviolet light) curing adhesive, and typically employs an acrylic resin, epoxy resin, polyester, or polyolefin. The use of ultraviolet light curable epoxy resin-based adhesives, which display excellent curability even without heating, is particularly preferred.

e: Drying Means

The drying means 142 can be formed using a physical drying agent such as zeolite, silica gel, carbon, or carbon nanotubes, a chemical drying agent such as an alkali metal oxide, a metal halide, or chlorine peroxide, a drying agent comprising an organo metallic complex dissolved in a petroleum-based solvent such as toluene, xylene, or an aliphatic organic solvent, anddrying agents comprising drying agent particles dispersed within a binder such as a transparent polyethylene, polyisoprene, or polyvinyl cinnamate.

f: Different Systems for the Organic EL Panel

An organic EL panel 100 according to an embodiment of the present invention can under go various design modifications without departing from the scope of the present invention. For example, the emission configuration for the organic EL devices 130 may be either the bottom emission system described above, in which light is emitted through the substrate 110 side of the structure, or a top emission system in which light is emitted through the opposite side from the substrate 110. Furthermore, the organic EL panel 100 may be either for monochromatic display or color display. Possible methods that can be used to achieve color display include the obvious separate deposition method; methods which incorporate a color conversion layer, which uses either color filters or a fluorescent material to generate color from single-color light such as white or blue light emitted from a monochromatic luminescent layer (CF method, and CCM method); methods in which electromagnetic waves are irradiated at the emission area of a monochromatic luminescent layer, thereby generating color emission (photobleaching methods); and methods in which unit display regions of two or more colors are laminated together, forming a single new unit display region (SOLED (transparent stacked OLED) methods).

In the embodiment of the present invention described above, a vacuum film formation apparatus is used for forming a thin film on a film formation target surface, by irradiating an atomic flow or molecular flow, generated by heating and either subliming or vaporizing a film forming material, onto the film formation target surface. The film formation source of this vacuum film formation apparatus comprises a material container for housing the film forming material, heating means for heating the film forming material inside the material container, and a rectifier provided at the ejection port of the material container. This rectifier comprises a passage partitioned into fine openings, and a set level of directivity can be obtained based on the cross-sectional area Sa of each opening within the rectifier, the distance L from the ejection tip of the rectifier to the film formation target surface, and the film formation rate R of the film forming material at a point on the film formation target surface directly above the center of the rectifier.

Accordingly, the directivity of the film formation source can be set on the basis of the molecular flow density, which is the primary factor controlling the directivity, meaning a film formation source can be designed that is capable of providing a higher level of directivity with no reduction in the film formation rate. Using this film formation source, a vacuum film formation apparatus capable of conducting film formation at a reasonable rate and with a level of directivity can be produced. Furthermore, because the invention enables film formation to be conducted with a high level of directivity and favorable operational efficiency, the manufacturing costs of organic EL devices can be reduced, while the product quality is improved.

While there has been described what are at present considered to be preferred embodiments of the present invention, it will be understood that various modifications may be made thereto, and it is intended that the appended claims cover all such modifications as fall within the true spirit and scope of the invention.

1. A film formation source of a vacuum film formation apparatus, for forming a thin film on a film formation target surface by irradiating an atomic flow or molecular flow, generated by heating, and either subliming or vaporizing, a film forming material, onto the film formation target surface, the film formation source comprising:
a material container for housing the film forming material;
heating means for heating the film forming material inside the material container; and
a rectifier provided at an ejection port of the material container, wherein:
the rectifier comprises a passage partitioned into fine openings; and
a set directivity is obtained based on a cross-sectional area Sa of each opening within the rectifier, a distance L from an ejection tip of the rectifier to the film formation target surface, and a film formation rate R for the film forming material at a point on the film formation target surface directly above the center of the rectifier.

2. The film formation source according to claim 1, wherein a relationship among the cross-sectional area Sa of each opening within the rectifier, the distance L from the ejection tip of the rectifier to the film formation target surface, the film formation rate R of the film forming material at the point on the film formation target surface directly above the center of the rectifier, and a half width ha during film formation is represented by the formula (1) shown below:
1≦X≦10, 0.01≦Y≦0.21·X−0.2 (1)
wherein X=log(R·L²/Sa) [angstrom/sec], and Y=ha/L.

3. The film formation source according to claim 1, wherein
a relationship among the cross-sectional area Sa of each opening within the rectifier, the distance L from the ejection tip of the rectifier to the film formation target surface, the film formation rate R of the film forming material at the point on the film formation target surface directly above the center of the rectifier, and a half width ha during film formation is represented by the formula (2) shown below:
2≦X≦9, 0.05≦Y≦0.22·X−0.39 (2),
wherein X=log(R·L²/Sa) [angstrom/sec], and Y=ha/L.

4. The film formation source according to claim 1, wherein the rectifier is provided at the ejection port which has a smaller diameter than a diameter of the material container.

5. The film formation source according to claim 1, wherein the rectifier is produced by filling an inside of a circular cylindrical body with narrow diameter pipes, thereby forming the openings.

6. A vacuum film formation apparatus, comprising:
the film formation source according to claim 2; and
a vacuum film formation chamber holding a substrate comprising the film formation target surface, wherein
an atomic flow or molecular flow of the film forming material ejected from the film formation source is irradiated onto the substrate.

7. A method of manufacturing an organic EL device, using the vacuum film formation apparatus according to claim 6 for forming at least one electrode layer or at least one organic material layer on the substrate.

8. An organic EL device manufactured using the manufacturing method according to claim 7.

9. A vacuum film formation apparatus, comprising:
the film formation source according to claim 3; and
a vacuum film formation chamber holding a substrate comprising the film formation target surface, wherein
an atomic flow or molecular flow of the film forming material ejected from the film formation source is irradiated onto the substrate.
